(19) United States
(12) Patent Application Publication
(10) Pub. No.: US 2026/0273688 A1
(43) Pub. Date: Sep. 17, 2026

(54) POSITION SETTING METHOD OF THICKNESS MEASURER, AND GRINDING APPARATUS

(71) Applicant: Tokyo Electron Limited, Tokyo (JP)

(72) Inventors: Masakazu YARIMITSU, Kikuchi-gun, Kumamoto (JP); Takashi SAKAUE, Kikuchi-gun, Kumamoto (JP); Nobutaka FUKUNAGA, Kikuchi-gun, Kumamoto (JP)

(21) Appl. No.: 19/167,932

(22) PCT Filed: Feb. 28, 2024
(86) PCT No.: PCT/JP2024/007362

§ 371 Date: Sep. 23, 2025

(30) Foreign Application Priority Data
Mar. 24, 2023 (JP) 2023-047617

(51) Int. Cl. B24B 49/04; B24B 49/12

(52) U.S. Cl. CPC B24B 49/045; B24B 49/12

(57) ABSTRACT

A position setting method of a thickness measurer configured to measure a thickness of a substrate by using measurement light in a grinding apparatus configured to grind the substrate includes: holding a calibration substrate with a substrate holder; irradiating the calibration substrate with the measurement light from the thickness measurer, while moving the thickness measurer closer to or away from the calibration substrate; acquiring intensity of reflection light of the measurement light reflected on the calibration substrate; and setting a position of the thickness measurer at which the acquired intensity of the reflection light becomes an optimal value as a thickness measurement position of the substrate.

### TECHNICAL FIELD

The various aspects and embodiments described herein pertain generally to a position setting method of a substrate thickness measurer and a grinding apparatus.

### BACKGROUND

Patent document 1 discloses a method of self-grinding a substrate holding device in a processing apparatus. In this self-grinding, a top surface of the substrate holding device is ground by using a grindstone to improve parallelism between a grinder and the top surface of the substrate holding device.

### PRIOR ART DOCUMENT

Patent Document 1: Japanese Patent Laid-open Publication No. 2021-137883

### DISCLOSURE OF THE INVENTION

### Problems to be Solved by the Invention

Exemplary embodiments provide a technique enabling appropriate position setting of a thickness measurer configured to measure a thickness of a substrate by using measurement light in a grinding apparatus that grinds the substrate.

### Means for Solving the Problems

In an exemplary embodiment, a position setting method of a thickness measurer configured to measure a thickness of a substrate by using measurement light in a grinding apparatus configured to grind the substrate includes: holding a calibration substrate with a substrate holder; irradiating the calibration substrate with the measurement light from the thickness measurer, while moving the thickness measurer closer to or away from the calibration substrate; acquiring intensity of reflection light of the measurement light reflected on the calibration substrate; and setting a position of the thickness measurer at which the acquired intensity of the reflection light becomes an optimal value as a thickness measurement position of the substrate. Further, in the present exemplary embodiment, grinding includes polishing.

### Effect of the Invention

According to the exemplary embodiments, it is possible to appropriately set the position of the thickness measurer configured to measure the thickness of the substrate by using the measurement light in the grinding apparatus that grinds the substrate.

### BRIEF DESCRIPTION OF THE DRAWINGS

FIG. 1 is a plan view illustrating a schematic configuration of a grinding apparatus according to an exemplary embodiment.

FIG. 2 is a side view illustrating a configuration of a grinding module and a chuck.

FIG. 3 is a side view illustrating a schematic configuration of a thickness measurement module.

FIG. 4 is an explanatory diagram illustrating an example of an operation screen displayed on a display panel.

FIG. 5 is a flowchart illustrating a method of performing automatic Z-axis setting of a sensor after performing self-grinding of the chuck.

FIG. 6 is an explanatory diagram illustrating a state in which the automatic Z-setting of the sensor is being performed.

FIG. 7 is an explanatory diagram showing a relationship between a Z-axis position of the sensor and intensity of reflected light.

FIG. 8 is an explanatory diagram illustrating a state in which Z-axis setting of the sensor is being performed using a block gauge.

FIG. 9A and FIG. 9B are explanatory diagrams illustrating a state in which the sensor is being moved during grinding after the automatic Z-axis setting of the sensor is performed.

FIG. 10A to FIG. 10C are explanatory diagrams illustrating a state in which a radial position of the sensor is being set.

FIG. 11 is an explanatory diagram illustrating a state in which a radial position of the sensor is being set.

### DETAILED DESCRIPTION

In a semiconductor manufacturing process, a semiconductor substrate (hereafter, simply referred to as “wafer”) is thinned by grinding a rear surface of the wafer. The grinding of the rear surface of the wafer is performed by bringing a grinding whetstone of a grinder into contact with the rear surface of the wafer whose front surface is held by a chuck, while rotating the chuck.

Here, grinding residues and the like generated by the grinding of the wafer may be deposited on a top surface of the chuck, which may reduce the parallelism between the grinding whetstone of the grinder and the top surface of the chuck. As a resolution, the top surface of the chuck may be ground by the grinder to improve the parallelism between a bottom surface of the grinding whetstone of the grinder and the top surface of the chuck, that is, so-called “self-grinding” may be performed. This self-grinding is sometimes referred to as chuck grinding.

In addition, in order to grind the wafer to a required thickness, this grinding of the wafer is performed while measuring the thickness of the wafer using a measurer. The measurer may be, by way of example, of a non-contact type, and has a sensor that measures the thickness of the wafer without coming into contact with the wafer. The sensor irradiates the wafer with measurement light, and receives reflected light from a front surface of the wafer and reflected light from a rear surface of the wafer. The thickness of the wafer is calculated based on the reflected light from the front and rear surfaces received by the sensor.

When the above-described self-grinding is performed, the thickness of the chuck becomes smaller, so the distance between the sensor of the measurer and the top surface of the chuck changes before and after the self-grinding. In such a case, the measurer may not properly measure the thickness of the wafer, and the wafer may not be formed to have a required thickness. Therefore, it is necessary to adjust the position of the sensor after the self-grinding, but the self-grinding method disclosed in Patent Document 1 does not take into consideration this adjustment and setting of the position of the sensor.

In view of the foregoing, the exemplary embodiments provide a technique enabling appropriate setting of a position of a thickness measurer configured to measure the thickness of a substrate by using measurement light in a grinding apparatus that grinds the substrate. Hereinafter, a grinding apparatus and a position setting method of a thickness measurer according to an exemplary embodiment will be described with reference to the accompanying drawings. In the present specification and the drawings, parts having substantially the same functions and configurations will be assigned same reference numerals, and redundant descriptions thereof will be omitted.

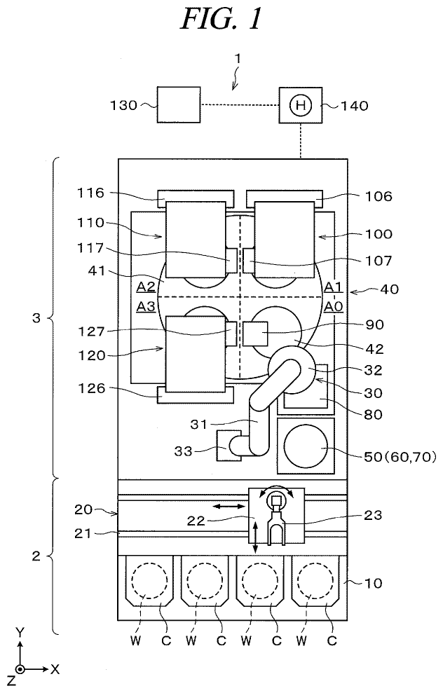

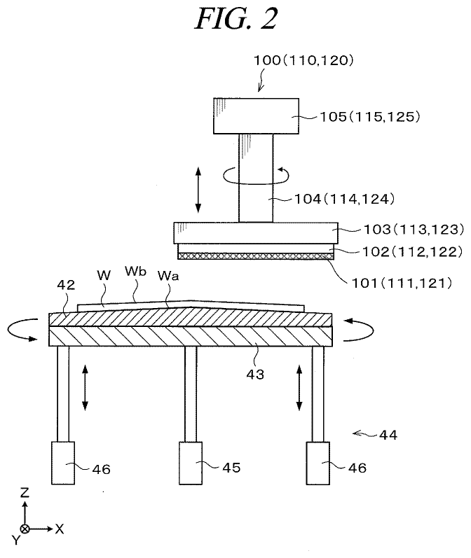

In a grinding apparatus 1 shown in FIG. 1, a wafer W as a substrate is ground to be thinned. The wafer W is, for example, a semiconductor wafer such as, but not limited to, a silicon wafer or a compound semiconductor wafer. As illustrated in FIG. 2, a front surface Wa of the wafer W is a holding surface that is held by a chuck 42 to be described later in the grinding apparatus 1. Further, a rear surface Wb of the wafer W, which is opposite to the front surface Wa, is a grinding surface that is ground in the grinding apparatus 1.

As depicted in FIG. 1, the grinding apparatus 1 has a configuration in which a carry-in/out station 2 and a processing station 3 are connected as a single structure. In the carry-in/out station 2, a cassette C capable of accommodating a plurality of wafers W is carried in and out to/from, for example, the outside. The processing station 3 is equipped with various types of processing apparatuses each configured to perform a required processing on the wafer W.

A cassette placement table 10 is provided in the carry-in/out station 2. A wafer transfer section 20 is provided adjacent to the cassette placement table 10 on the positive Y-axis side of the cassette placement table 10.

A wafer transfer device 22, which is configured to be movable on a transfer path 21 extending in the X-axis direction, is provided in the wafer transfer section 20. The wafer transfer device 22 has a transfer fork 23 that holds and transfers the wafer W. The transfer fork 23 is configured to be movable in a horizontal direction, a vertical direction, around a horizontal axis, and around a vertical axis. Also, the wafer transfer device 22 is configured to be able to transfer the wafer W to/from the cassette C on the cassette placement table 10, an alignment device 50 to be described later, and a first cleaner 60 to be described later.

In the processing station 3, a processing such as grinding and cleaning is performed on the wafer W. The processing station 3 has a transferrer 30 configured to transfer the wafer W, a grinding module 40 configured to grind the wafer W, the alignment device 50 configured to adjust a direction of the wafer W in the horizontal direction, the first cleaner 60 configured to clean the wafer W after being ground, a calibration wafer storage 70 that stores a calibration wafer as a calibration substrate, and a second cleaner 80 configured to clean the wafer W after being ground.

The transferrer 30 as a transfer device is a multi-joint robot equipped with a plurality of, e.g., three arms 31. Each of the three arms 31 is configured to be rotatable. A transfer pad 32 configured to attract and hold the wafer W is mounted to the arm 31 at a leading end. The arm 31 at a base end is mounted to an elevating mechanism 33 configured to move the arm 31 up and down in the vertical direction. The transferrer 30 is configured to be able to transfer the wafer W to/from the grinding module 40, the alignment device 50, the first cleaner 60, and the second cleaner 80. Further, the transferrer 30 is also configured to be able to transfer the calibration wafer to/from the grinding module 40 and the calibration wafer storage 70.

The grinding module 40 has a rotary table 41. Four chucks 42 serving as substrate holders each configured to attract and hold the wafer W are provided on the rotary table 41. By way of example, a porous chuck is used as the chuck 42. A surface of the chuck 42, i.e., a holding surface for the wafer W, has a convex shape with its central portion protruding higher than its edge portion when viewed from the side. Although this protrusion of the central portion is actually very minute, it may be illustrated in a rather exaggerated manner in the following description for the clarity of explanation.

As shown in FIG. 2, the four chucks 42 are held by four chuck bases 43, respectively. Each of the chuck bases 43 is provided with an inclination adjusting mechanism 44 configured to adjust a relative inclination between the chuck 42 and corresponding one of grinders (a rough grinder 100, an intermediate grinder 110, and a finishing grinder 120 to be described later). The inclination adjusting mechanism 44 has a fixed shaft 45 provided on a bottom surface of the chuck base 43 and multiple, for example, two elevating shafts 46. Each elevating shaft 46 is configured to be extensible and contractible, and serves to move the chuck base 43 up and down. The inclination adjusting mechanism 44 raises and lowers one end of an outer periphery of the chuck base 43 in the vertical direction by the elevating shafts 46 with respect to the other end (the position corresponding to the fixed shaft 45), thereby allowing the chuck 42 and the chuck base 43 to be inclined. This allows a relative inclination between a grinding surface of each grinder at a processing position A1 (A2, A3) and the top surface of the chuck 42 to be adjusted. The configuration of the inclination adjusting mechanism 44 is not limited to the above, and any of various configurations may be adopted as long as the relative angle (parallelism) of the surface (holding surface) of the chuck 42 with respect to the grinding surface of each grinder can be adjusted.

As shown in FIG. 1, the four chucks 42 can be moved to a delivery position A0 and the processing positions A1 to A3 as the rotary table 41 is rotated. Further, each of the four chucks 42 is configured to be rotatable around a vertical axis by a non-illustrated rotating mechanism.

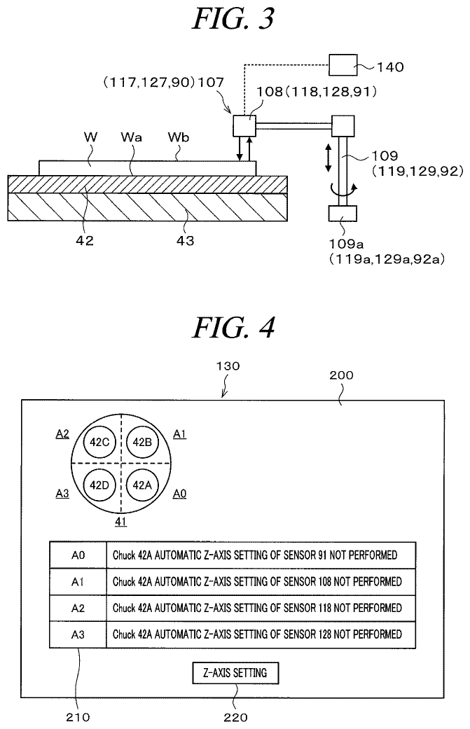

At the delivery position A0, the wafer W is delivered by the transferer 30. At the delivery position A0, a thickness measurement module 90 is provided to measure the thickness of the wafer W before or after being ground. The thickness measurement module 90 measures the thickness of the wafer W at multiple points, for example, three points (a center point, a mid-point, and an outer peripheral point) that are equally spaced in a radial direction. The thickness measurement module 90 also obtains in-surface distribution of the thickness of the wafer W, and calculates a flatness (total thickness variation (TTV)) of the wafer W. The thickness measurement module 90 may have any configuration, but has the same configuration as a thickness measurement module 107 shown in FIG. 3, which will be described later. That is, the thickness measurement module 90 has a sensor (probe) 91 as a thickness measurer, and a moving mechanism 92. The moving mechanism 92 has a driver 92a, and serves to raise and lower the sensor 91 and, also, to move the sensor 91 in the radial direction of the wafer W.

The present exemplary embodiment will be described for the example where the thickness measurement module 90 is provided at the delivery position AO, but the location of the thickness measurement module 90 is not limited thereto. By way of example, the thickness measurement module 90 may be disposed separately from the grinding module 40.

As shown in FIG. 1, the rough grinder 100 is disposed at the processing position A1 to roughly grind the wafer W. The intermediate grinder 110 is disposed at the processing position A2 to grind the wafer W to an intermediate level. The finishing grinder 120 is arranged at the processing position A3 to finely grind the wafer W.

As shown in FIG. 2, the rough grinder 100 at the processing position A1 has an annular rough grinding whetstone 101, a rough grinding wheel 102 supporting the rough grinding whetstone 101, a mount 103 supporting the rough grinding wheel 102, a spindle 104 that rotates the rough grinding wheel 102 via the mount 103, and a driver 105 supporting the spindle 104. The driver 105 has, for example, a motor (not shown) embedded therein, and serves to rotate the spindle 104. Also, as shown in FIG. 1, the rough grinder 100 is configured to be movable in the vertical direction along a support column 106 by a driver (not shown).

Here, as stated above, the holding surface of the chuck 42 has the convex shape. For this reason, when grinding the wafer W by using the rough grinder 100, a part of the annular rough grinding whetstone 101 comes into contact with the wafer W. More specifically, the annular rough grinding whetstone 101 comes into contact with the wafer W in an arc line shape, ranging from the center to the outer edge of the wafer. In this state, the chuck 42 and the rough grinding wheel 102 are respectively rotated, so that the entire rear surface Wb of the wafer W is ground.

Also, the thickness measurement module 107 configured to measure the thickness of the wafer W is provided at the processing position A1. As illustrated in FIG. 3, the thickness measurement module 107 has a sensor (probe) 108 as a thickness measurer, and a moving mechanism 109 configured to raise and lower the sensor 108. The sensor 108 is of a non-contact type that measures the thickness of the wafer W without coming into contact with the wafer W, and for example, a white light confocal type optical sensor is used. The sensor 108 irradiates the wafer W with measurement light, and receives reflected light from the front surface Wa of the wafer W and reflected light from the rear surface Wb. A signal of a measurement result by the sensor 108 is output to the controller 140 to be described later, and the controller 140 calculates the thickness of the wafer W based on the reflected light from both the front and rear surfaces Wa and Wb received by the sensor. The moving mechanism 109 has a driver 109a, and moves the sensor 108 up and down and in the radial direction of the wafer W. In the present exemplary embodiment, the moving mechanism 109 rotates the sensor 108 around the driver 109a to move it in the radial direction of the wafer W, but the sensor 108 may be moved linearly.

Further, in the present exemplary embodiment, the white light confocal optical sensor is used for the sensor 108 of the thickness measurement module 107, but the configuration of the thickness measurement module 107 is not limited to the above, and any measurement module may be used as long as it measures the thickness of the wafer W in a non-contact manner. In addition, the sensor 108 may be provided in plurality. Further, the measurement light radiated from the sensor 108 is not particularly limited, and may be pulsed light or continuous light as long as it can be received by the sensor 108 as the reflected light.

The intermediate grinder 110 at the processing position A2 has the same configuration as the rough grinder 100. That is, as shown in FIG. 2, the intermediate grinder 110 has an annular intermediate grinding whetstone 111, an intermediate grinding wheel 112, a mount 113, a spindle 114, a driver 115, and a support column 116. The particle size of abrasive grains of the intermediate grinding whetstone is smaller than that of the rough grinding whetstone.

As illustrated in FIG. 1, a thickness measurement module 117 for measuring the thickness of the wafer W is provided at the processing position A2. As shown in FIG. 3, the thickness measurement module 117 has the same configuration as the thickness measurement module 107 described above, that is, it has a sensor (probe) 118 as a thickness measurer and a moving mechanism 119 equipped with a driver 119a.

The finishing grinder 120 at the processing position A3 has the same configuration as the rough grinder 100. That is, as shown in FIG. 2, the finishing grinder 120 has an annular finishing grinding whetstone 121, a finishing grinding wheel 122, a mount 123, a spindle 124, a driver 125, and a support column 126. The particle size of abrasive grains of the finishing grinding whetstone is smaller than that of the intermediate grinding whetstone.

In addition, as depicted in FIG. 1, a thickness measurement module 127 configured to measure the thickness of the wafer W is provided at the processing position A3. As shown in FIG. 3, the thickness measurement module 127 has the same configuration as the thickness measurement module 107 described above, that is, it has a sensor (probe) 128 as a thickness measurer and a moving mechanism 129 equipped with a driver 129a.

The grinding apparatus 1 as described above is provided with a display panel 130, as illustrated in FIG. 1. The display panel 130 is, for example, a monitor or a touch panel, and may be directly mounted to the grinding apparatus 1 or may be monitored remotely. The display panel 130 displays a screen for operating each processing performed in the grinding apparatus 1. By way of example, the display panel 130 displays an operation screen for automatically setting the positions of the sensors 91, 108, 118, and 128 after the self-grinding of the chuck 42. The operation screen for automatically setting the positions of the sensors 91, 108, 118, and 128 will be elaborated later. A signal of an operation setting result on the display panel 130 is output to the controller 140 to be described below.

The above-described grinding apparatus 1 is equipped with at least one controller 140. The controller 140 processes computer executable instructions that cause the grinding apparatus 1 to perform various processes described in the present disclosure. The controller 140 may be configured to control the individual components of the grinding apparatus 1 to perform the various processes described herein. In one embodiment, a part or the whole of the controller 140 may be included in the grinding apparatus 1. The controller 140 may include a processor, a storage, and a communication interface. The controller 140 is implemented by, for example, a computer. The processor may be configured to read out, from the storage, a program that provides logic or routines that enable various control operations to be performed, and to execute the read program to perform the various control operations. This program may be stored in the storage in advance, or may be obtained via a medium when necessary. The acquired program is stored in the storage, and is read from the storage and executed by the processor. The medium may be any of various computer-readable recording media, or may be a communication line connected to the communication interface. The recording medium may be transitory or non-transitory. The processor may be a central processing unit (CPU), or one or more circuits. The storage may include a random access memory (RAM) a read only memory (ROM), a hard disk drive (HDD), a solid state drive (SSD), or a combination of these. The communication interface may communicate with the grinding apparatus 1 via a communication line such as a local area network (LAN).

Now, a series of processes of a wafer processing performed in the grinding apparatus 1 configured as above will be explained.

First, the cassette C accommodating the plurality of wafers W is placed on the cassette placement table 10 of the carry-in/out station 2. Then, the wafer W in the cassette C is taken out by the transfer fork 23 of the wafer transfer device 22 and transferred to the processing station 3. The wafer W transferred to the processing station 3 is delivered to the alignment device 50. In the alignment device 50, the direction of the wafer W in the horizontal direction is adjusted by adjusting the position of a notch (not shown) formed on the wafer W.

Subsequently, the wafer W is transferred by the transferer 30 from the alignment device 50 to the grinding module 40 and handed over to the chuck 42 at the delivery position A0. At the delivery position A0, the thickness of the wafer W before being ground is measured at multiple points by the thickness measurement module 90 and the controller 140. Although the thickness measurement points on the wafer W by the thickness measurement module 90 are not particularly limited, they may be three points equally spaced in the radial direction, for example. A first measurement point is a center point of the wafer W. A second measurement point is a mid-point of the wafer W, which corresponds to a position of R/2 from the center when the radius of the wafer W is denoted by R. A third measurement point is an outer peripheral point of the wafer W.

Next, the wafer W held by the chuck 42 is moved to the processing positions A1 to A3 sequentially. At the processing position A1, the rear surface Wb of the wafer W is roughly ground by the rough grinder 100. At the processing position A2, the rear surface Wb of the wafer W is ground to the intermediate level by the intermediate grinder 110. At the processing position A3, the rear surface Wb of the wafer W is finely ground by the finishing grinder 120. These rough grinding, intermediate grinding, and finishing grinding are performed while measuring the thickness of the wafer W using the thickness measurement modules 107, 117, and 127, respectively, to grind the wafer W. The thickness measurement of the wafer W by the thickness measurement modules 107, 117, and 127 is performed at the mid-point of the wafer W.

After performing the rough grinding, intermediate grinding, and finishing grinding at the processing positions A1 to A3, respectively, the thickness of the wafer W is measured at multiple points using the thickness measurement modules 107, 117, and 127 and the controller 140 to obtain the in-surface distribution of the thickness of the wafer W and the flatness of the wafer W. Although the thickness measurement points on the wafer W by the thickness measurement modules 107, 117, and 127 are not particularly limited, they may be, for example, three points (center point, mid-point, and outer peripheral point) equally spaced in the radial direction. Then, based on the thickness measurement results, the elevating shafts 46 of the inclination adjusting mechanism 44 is adjusted to adjust the relative angle (parallelism) of the surface of the chuck 42 with respect to the grinding surfaces of the grinders 100, 110, and 120.

Next, the wafer W held by the chuck 42 is moved to the delivery position AO. At the delivery position A0, the thickness of the wafer W after the finishing grinding is measured at multiple points by the thickness measurement module 90 and the controller 140 to obtain the in-surface distribution of the thickness of the wafer W and the flatness of the wafer W. Although the thickness measurement points on the wafer W by the thickness measurement module 90 are not particularly limited, they may be, by way of example, three points (center point, mid-point, and outer peripheral point) equally spaced in the radial direction.

Thereafter, the wafer W is transferred from the delivery position AO to the second cleaner 80 by the transferrer 30, and the front surface Wa and/or the rear surface Wb are cleaned while being held on the transfer pad 32.

Then, the wafer W is transferred by the transferrer 30 from the second cleaner 80 to the first cleaner 60, where the front surface Wa and/or the rear surface Wb are further cleaned by using a cleaning liquid nozzle (not shown).

Afterwards, the wafer W that has been subjected to all the required processes is transferred by the transfer fork 23 of the wafer transfer device 22 to the cassette C on the cassette placement table 10. In this way, the series of processes of the wafer processing is completed.

Here, when the in-surface distribution of the thickness of the wafer W after being ground deviates from a target value, the self-grinding of each chuck 42 is performed.

In the self-grinding, the top surface of the chuck 42 is ground. In this case, since the thickness of the chuck 42 becomes smaller, the distance between the sensors 91, 108, 118, and 128 of the thickness measurement modules 90, 107, 117, and 127 and the top surface of the chuck 42 changes before and after the self-grinding. Therefore, it is necessary to reset the positions of the sensors 91, 108, 118, and 128. The positions of the sensors 91, 108, 118, and 128 are height positions (Z-axis positions) set by the moving mechanisms 92, 109, 119, and 129, respectively. In other words, the positions of the sensors 91, 108, 118, and 128 are the distances between the sensors 91, 108, 118, and 128 and the top surface of the chuck 42 (or the front surface Wa of the wafer W). In the following explanation, the position setting of the sensors 91, 108, 118, and 128 may be referred to as Z-axis setting, and in the present exemplary embodiment, such position setting is performed automatically and may be referred to as automatic Z-axis setting.

As shown in FIG. 4, an operation screen 200 for performing the automatic Z-axis setting of the sensors 91, 108, 118, and 128 is displayed on the display panel 130. The operation screen 200 displays the rotary table 41, an automatic Z-axis setting progress table 210, and a Z-axis setting button 220 as a position setting button.

As described above, the rotary table 41 is provided with the four chucks 42, and the operation screen 200 displays chucks 42A, 42B, 42C, and 42D as these four chucks 42.

The automatic Z-axis setting progress table 210 displays the progress of the automatic Z-axis setting of the sensors 91, 108, 118, and 128 for the chucks 42 after the self-grinding at the delivery position AO and the processing positions A1 to A3. The example of FIG. 4 shows a case where the target of the self-grinding is the chuck 42A. At the delivery position A0 and the processing positions A1 to A3, the automatic Z-axis setting of the sensors 91, 108, 118, and 128 after the self-grinding of the chuck 42A is not performed.

The Z-axis setting button 220 is a button for starting the automatic Z-axis setting of the sensors 91, 108, 118, and 128 after the self-grinding of the chucks 42. As will be described later, when the self-grinding of the chucks 42 is completed, the user presses the Z-axis setting button 220. A signal of the user's operation result is output to the controller 140, and the automatic Z-axis setting of the sensors 91, 108, 118, and 128 is started.

Now, a method of automatically setting the Z-axis of the sensors 91, 108, 118, and 128 after performing the self-grinding of, for example, the chuck 42A will be described.

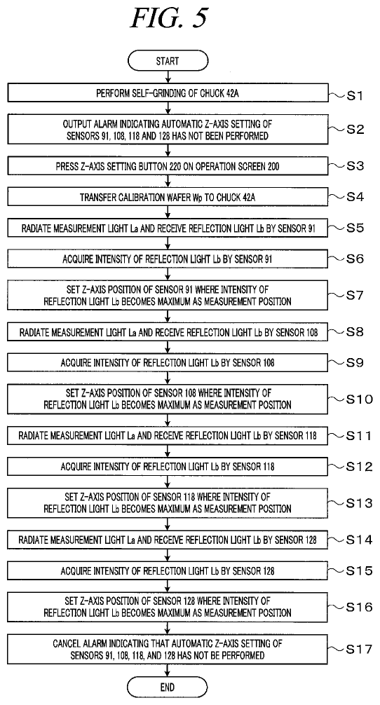

First, the self-grinding of the chuck 42A is performed (S1 in FIG. 5). By way of example, the self-grinding of the chuck 42A is performed by using the finishing grinder 120 at the processing position A3. In this case, the finishing grinding whetstone 121 and the finishing grinding wheel 122 in the finishing grinder 120 are replaced with a self-grinding whetstone and a self-grinding wheel, respectively. Then, with the self-grinding whetstone in contact with the top surface of the chuck 42, the self-grinding whetstone and the chuck 42 are rotated to grind the top surface of the chuck 42.

Upon the completion of the self-grinding of the chuck 42A in S1, an alarm is output to indicate that the automatic Z-axis setting of the sensors 91, 108, 118, and 128 has not been performed (S2 in FIG. 5). Specifically, in the automatic Z-axis setting progress table 210 on the operation screen 200, “Automatic Z-axis setting of sensor 91 not performed” is displayed at the delivery position A0. Likewise, “Automatic Z-axis setting of sensor 108 not performed” is displayed at the processing position A1, “Automatic Z-axis setting of sensor 118 not performed” is displayed at the processing position A2, and “Automatic Z-axis setting of sensor 128 not performed” is displayed at the processing position A3.

The way to output the alarm indicating that the automatic Z-axis setting has not been performed is not particularly limited. By way of example, an audible alert may be set forth. Also, while the alarm indicating that the Z-axis has not been automatically set is being output, the grinding of the wafer W may not be performed.

Next, the Z-axis setting button 220 on the operation screen 200 is pressed by the user (S3 in FIG. 5). A signal of the Z-axis setting button 220 being pressed is output to the controller 140, and the controller 140 performs the automatic Z-axis setting of the sensors 91, 108, 118, and 128 sequentially.

The automatic Z-axis setting of the sensors 91, 108, 118, and 128 is performed by using a calibration wafer Wp stored in a calibration wafer storage 70. The thickness of the calibration wafer Wp is a known value and identified in advance.

When automatically setting the Z-axis of the sensors 91, 108, 118, and 128, first, the calibration wafer Wp stored in the calibration wafer storage 70 is taken out and transferred by the transferer 30 to the grinding module 40, and delivered onto the chuck 42A designated on the operation screen 200 at the delivery position A0 (S4 in FIG. 5).

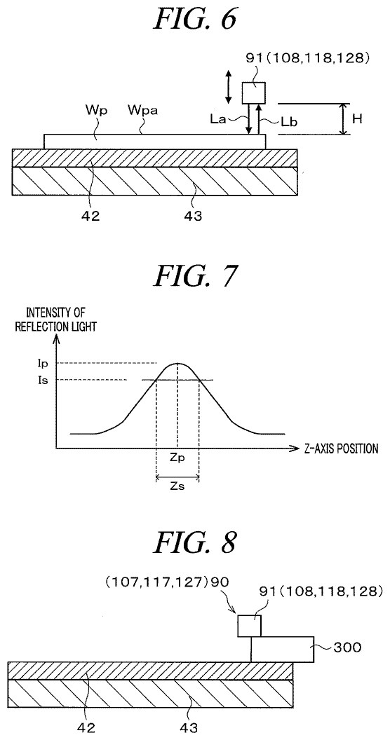

At the delivery position A0, as shown in FIG. 6, measurement light La is radiated from the sensor 91 to the top surface Wpa of the calibration wafer Wp, while moving the sensor 91 up and down, i.e., moving the sensor 91 closer to or away from the calibration wafer Wp. The sensor 91 then receives reflection light Lb of the measurement light La reflected on the top surface Wpa of the calibration wafer Wp (S5 in FIG. 5).

A signal of the measurement result by the sensor 91 is output to the controller 140, and the controller 140 obtains the intensity of the reflection light Lb shown in FIG. 7, for example (S6 in FIG. 5). A horizontal axis in FIG. 7 indicates the Z-axis position (height position) of the sensor 91, and a vertical axis indicates the intensity of the reflection light Lb.

The controller 140 sets, as a measurement position of the sensor 91, a Z-axis position Zp of the sensor 91 where the intensity of the reflection light Lb becomes a maximum intensity Ip (S7 in FIG. 5). The Z-axis position Zp of the sensor 91 where the intensity of the reflection light Lb becomes the maximum intensity Ip is a position where the distance between the bottom surface of the sensor 91 and the top surface Wpa of the calibration wafer Wp becomes an optimal distance H, as shown in FIG. 6. The optimal distance H is a distance that is set according to the specifications of the sensor 91, and is a distance at which the sensor 91 can optimally measure a measurement target.

In this way, in S7, the intensity of the reflection light Lb when setting the measurement position of the sensor 91 is set to the maximum intensity Ip. However, the exemplary embodiment is not limited thereto. For example, as shown in FIG. 7, the intensity of the reflection light Lb may be an optimal intensity Is lower than the maximum intensity Ip. The distance between the bottom surface of the sensor 91 and the top surface Wpa of the calibration wafer Wp shown in FIG. 6 may be within a tolerance range from the optimal distance H of the sensor 91 according to its specifications. A Z-axis position range Zs of the sensor 91 where the intensity of the reflection light Lb becomes the optimal intensity Is is a position within this tolerance range.

Subsequently, the calibration wafer Wp held by the chuck 42A is moved to the processing position A1. At the processing position A1, a measurement position of the sensor 108 is set in the same manner as in setting the measurement position of the sensor 91 at the delivery position A0. That is, the same as in S5, while moving the sensor 108 up and down, the measurement light La of the sensor 108 is radiated, and the reflection light Lb is received (S8 in FIG. 5). Then, as in S6, the intensity of the reflection light Lb is obtained (S9 in FIG. 5). As in S7, the Z-axis position Zp of the sensor 108 where the intensity of the reflection light Lb becomes the maximum intensity Ip is set as the measurement position of the sensor 108 (S10 in FIG. 5).

Next, the calibration wafer Wp held by the chuck 42A is moved to the processing position A2. At the processing position A2, a measurement position of the sensor 118 is set in the same manner as in setting the measurement position of the sensor 91 at the delivery position A0. That is, as in S5, while moving the sensor 118 up and down, the measurement light La of the sensor 118 is radiated, and the reflection light Lb is received (S11 in FIG. 5). As in S6, the intensity of the reflection light Lb is obtained (S12 in FIG. 5). As in S7, the Z-axis position Zp of the sensor 118 at which the intensity of the reflection light Lb becomes the maximum intensity Ip is set as the measurement position of the sensor 118 (S13 in FIG. 5).

Thereafter, the calibration wafer Wp held by the chuck 42A is moved to the processing position A3. At the processing position A3, a measurement position of the sensor 128 is set in the same manner as in setting the measurement position of the sensor 91 at the delivery position A0. That is, as in S5, while moving the sensor 128 up and down, the measurement light La of the sensor 128 is radiated, and the reflection light Lb is received (S14 in FIG. 5). As in S6, the intensity of the reflection light Lb is acquired (S15 in FIG. 5). As in S7, the Z-axis position Zp of the sensor 128 where the intensity of the reflection light Lb becomes the maximum intensity Ip is set as the measurement position of the sensor 128 (S16 in FIG. 5).

After the automatic Z-axis setting of the sensors 91, 108, 118, and 128 is performed as described above, the alarm outputted in S2, which indicates that the automatic Z-axis setting has not been performed, is canceled (S17 in FIG. 5). Specifically, in the automatic Z-axis setting progress table 210 on the operation screen 200, the message “Automatic Z-axis setting of sensors 91, 108, 118, and 128 not performed” at the processing positions A1, A2, and A3 disappears. Alternatively, the message changes to, for example, “Automatic Z-axis setting of sensors 91, 108, 118, and 128 completed”, which indicates that the Z-axis adjustment of the sensors 91, 108, 118, and 128 has been performed.

Upon the completion of the automatic Z-axis setting of the sensors 91, 108, 118, and 128, the calibration wafer Wp held by the chuck 42A is moved to the delivery position A0, and then transferred to the calibration wafer storage 70 by the transferrer 30.

Although the above exemplary embodiment has been described for the case where the chuck 42A is self-ground in S1, the same applies to the case where the other chucks 42B to 42D are self-ground.

According to the above-described exemplary embodiment, even if the thickness of the chuck 42 becomes small after it is self-ground, the measurement positions of the sensors 91, 108, 118, and 128 can be automatically adjusted to the appropriate positions by performing the automatic Z-axis setting of the sensors 91, 108, 118, and 128. As a result, the thickness of the wafer W before being ground, the thickness of the wafer W after being subjected to the rough grinding by the rough grinder 100, the thickness of the wafer W after being subjected to the intermediate grinding by the intermediate grinder 110, and the thickness of the wafer W after being subjected to the finishing grinding by the finishing grinder 120 can be set to a required thickness, and the wafer W can finally be formed to have the required thickness.

Here, after the self-grinding of the chuck 42, it may be possible to perform the Z-axis setting of the sensors 91, 108, 118, and 128 by using a block gauge 300 as shown in FIG. 8. That is, a maintenance panel of the grinding apparatus 1 is opened, and the Z-axis setting of the sensors 91, 108, 118, and 128 is performed by inserting the block gauge 300 between the chuck 42 and the sensors 91, 108, 118, and 128. However, in such a case, the Z-axis setting of the sensors 91, 108, 118, and 128 is manually performed by the user, which takes time and as poor operability. In addition, since the setting depends on the ability of the user, the accuracy of the Z-axis setting might be low.

In this respect, according to the present exemplary embodiment, when the Z-axis setting button 220 on the operation screen 200 is pressed in S3, the Z-axis setting of the sensors 91, 108, 118, and 128 is automatically performed. Therefore, the Z-axis setting can be performed in a short time. Also, there is no need to open the maintenance panel of the grinding apparatus 1, and the operability of the Z-axis setting can be improved. Furthermore, the Z-axis setting can be performed automatically without depending on the ability of the user, so that the accuracy of the Z-axis setting can be improved.

Further, in the present exemplary embodiment, when the self-grinding of the chuck 42 is completed in S1, the alarm indicating that the automatic Z-axis setting of the sensors 91, 108, 118, and 128 has not been performed is output in S2. This allows the user to check whether the automatic Z-axis setting of the sensors 91, 108, 118, and 128 has been performed or not.

In addition, by controlling the wafer W not to be ground while the alarm indicating that the automatic Z-axis setting of the sensors 91, 108, 118, 128 has not been performed is being output in S2, a failure to grind the wafer W to the required thickness can be avoided, so that the yield of product wafers can be improved.

After the automatic Z-axis setting of the sensors 91, 108, 118, and 128 is performed by using the calibration wafer Wp as in the above-described exemplary embodiment, the rough grinding by the rough grinder 100, the intermediate grinding by the intermediate grinder 110, and the finishing grinding by the finishing grinder 120 are performed on the wafer W in sequence. At this time, if the thickness of the calibration wafer Wp is different from the thickness of the wafer W before the grinding, the sensors 108, 118, and 128 are moved to correspond to the thickness of the wafer W before the grinding.

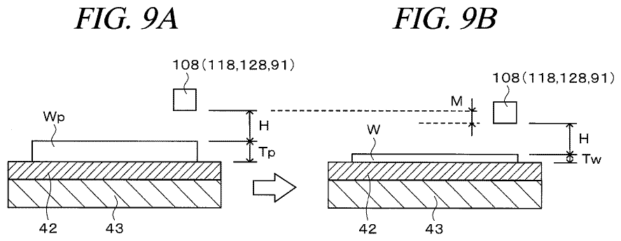

By way of example, assume that the thickness of the calibration wafer Wp is Tp, as shown in FIG. 9A, and the thickness of the wafer W before being subjected to the rough grinding is Tw, as shown in FIG. 9B. The thickness Tw of the wafer W before the rough grinding may be measured by using, for example, the thickness measurement module 90 at the delivery position A0, or may be obtained before the wafer W is carried into the grinding apparatus 1. In the present example, the thickness Tw of the wafer W before the rough grinding is smaller than the thickness Tp of the calibration wafer Wp. In this case, first, the automatic Z-axis setting of the sensor 108 is performed so that the distance between the bottom surface of the sensor 108 and the top surface Wpa of the calibration wafer Wp becomes the optimal distance H based on the thickness Tp of the calibration wafer Wp, as shown in FIG. 9A. Then, the sensor 108 is moved downwards by a distance M before the wafer W is roughly ground by the rough grinder 100, as shown in FIG. 9B. This distance M equals to a difference between the thickness Tp of the calibration wafer Wp and the thickness Tw of the wafer W before the rough grinding (M=Tp−Tw). In this way, when performing the rough grinding of the wafer W, the sensor 108 can be positioned at the optimal distance H, so that the thickness of the wafer W after the rough grinding can be made to a required thickness.

Although FIG. 9A and FIG. 9B illustrate the case where the wafer W is roughly ground by the rough grinder 100, the same applies to the intermediate grinding by the intermediate grinder 110 and the finishing grinding by the finishing grinder 120. In the intermediate grinding by the intermediate grinder 110, the thickness information of the wafer W before the intermediate grinding may be thickness information measured after the grinding by the rough grinder 100, or may be thickness information set in a recipe. In addition, in the finishing grinding by the finishing grinder 120, the thickness information of the wafer W before the finishing grinding may be thickness information measured after the intermediate grinding by the intermediate grinder 110, or may be thickness information set in the recipe.

Furthermore, at the delivery position AO before the grinding, if the thickness of the calibration wafer Wp is different from the thickness of the wafer W before the grinding, the sensor 91 may be moved to correspond to the thickness of the wafer W before the grinding. For example, the thickness of the wafer W before the grinding is acquired before the wafer W is carried into the grinding apparatus 1.

The above exemplary embodiment has been described for the case where the automatic Z-axis setting of the sensors 91, 108, 118, and 128 is performed after the self-grinding of the chuck 42. However, the timing of performing this automatic Z-axis setting is not limited to being after the self-grinding of the chuck 42. By way of example, when the distance between the chuck 42 and the sensors 91, 108, 118, and 128 has changed after replacing the chuck 42 or the sensors 91, 108, 118, and 128, the automatic Z-axis setting of the present exemplary embodiment may be performed.

In the above-described exemplary embodiment, the automatic Z-axis setting of the sensors 91, 108, 118, and 128 may be performed at the same positions in the radial direction (radial positions) as the measurement positions of the wafer W in the radial direction (radial measurement positions) when the thickness of the wafer W is measured by using the sensors 91, 108, 118, 128. In addition, the automatic Z-axis setting of the sensors 91, 108, 118, and 128 may be performed at multiple points in the radial direction of the calibration wafer Wp. In such a case, when the thickness measurement of the wafer W using the sensors 91, 108, 118, and 128 is performed at multiple measurement positions on the wafer W in the radial direction, the automatic Z-axis setting of the sensors 91, 108, 118, and 128 may be performed for each of multiple positions in the radial direction which are the same as the multiple measurement positions in the radial direction.

For example, when the thickness of the wafer W is measured at multiple points, for example, three points (center point, mid-point, and outer peripheral point) in the radial direction at the delivery position A0, the automatic Z-axis setting of the sensor 91 is performed by using the calibration wafer Wp for each of three points (center point, mid-point, and outer peripheral point) on the calibration wafer Wp in the radial direction. For example, the height position of the sensor 91 is set to a height position Z11 at the center point, a height position Z12 at the mid-point, and a height position Z13 at the outer peripheral point.

After performing the automatic Z-axis setting of the sensor 91 using the calibration wafer Wp as described above, the thickness of the wafer W before or after the grinding is measured at the delivery position AO. By way of example, when measuring the thicknesses of the wafer W at the center point, the mid-point, and the outer peripheral point in sequence, the sensor 91 is first placed at the height position Z11 to measure the thickness of the wafer W at the center point. Subsequently, the sensor 91 is placed at the height position Z12 to measure the thickness of the wafer W at the mid-point, and the sensor 91 is then placed at the height position Z13 to measure the thickness of the wafer W at the outer peripheral point.

Likewise, at each of the processing positions A1 to A3, the automatic Z-axis setting of the sensors 108, 118, and 128 is performed by using the calibration wafer Wp for each of the three points (center point, mid-point, outer peripheral point) on the calibration wafer Wp in the radial direction. For example, the height positions of the sensors 108, 118, and 128 are set to a height position Z21 at the center point, a height position Z22 at the mid-point, and a height position Z23 at the outer peripheral point.

Then, at each of the processing positions A1 to A3, the thickness of the wafer W at the mid-point is measured while the wafer W is being ground. At this time, the sensors 108, 118, and 128 are each placed at the height position Z22. After the wafer W is ground, the thickness of the wafer W is measured at the center point, the mid-point, and the outer peripheral point in sequence. At this time, each of the sensors 108, 118, and 128 is placed at the height positions Z21, Z22, and Z23 sequentially.

According to the present exemplary embodiment, since the automatic Z-axis setting positions of the sensors 91, 108, 118 and 128 in the radial direction are the same as the measurement positions on the wafer W in the radial direction, the thickness of the wafer W can be appropriately measured by adjusting the height positions of the sensors 91, 108, 118, and 128 at those radial positions.

Here, the horizontal movement of the sensors 91, 108, 118, and 128 by the moving mechanisms 92, 109, 119, and 129 may not be completely horizontal. Further, due to the chuck 42 being tilted, for example, the calibration wafer Wp held by the chuck 42 may not be completely horizontal. For this reason, the trajectory of the horizontal movement of the sensors 91, 108, 118, and 128 and the multiple points on the calibration wafer Wp in the radial direction are not necessarily parallel. Then, when the thickness measurement of the wafer W is performed at the multiple measurement positions in the radial direction, the appropriate height positions of the sensors 91, 108, 118, and 128 may also differ depending on the radial positions.

In this regard, according to the present exemplary embodiment, since the automatic Z-axis setting of the sensors 91, 108, 118, and 128 is performed at the multiple points in the radial direction and for each of the measurement points in the radial direction, the thickness of the wafer W can be appropriately measured at each of the measurement positions in the radial direction.

When the automatic Z-axis setting of the sensors 91, 108, 118, and 128 is performed at the multiple points in the radial direction as in the present exemplary embodiment, it is desirable to set the radial positions of the sensors 91, 108, 118, and 128 in advance. Below, a method of setting the radial position of the sensor 91 will be explained. The radial positions of the other sensors 108, 118, and 128 may be set in the same manner.

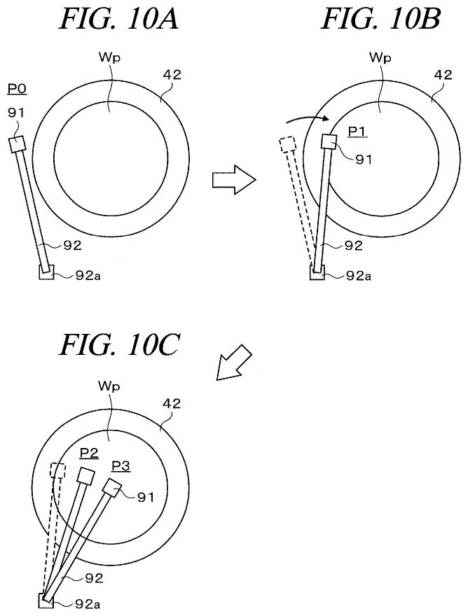

First, as shown in FIG. 10A, the calibration wafer Wp stored in the calibration wafer storage 70 is taken out and transferred by the transferrer 30 to the grinding module 40, and delivered on the chuck 42 at the delivery position A0. At this time, the sensor 91 is on standby at a position above and radially outside the calibration wafer Wp (standby position PO).

After the calibration wafer Wp is attracted to and held by the chuck 42, the sensor 91 is rotated by the moving mechanism 92 to be moved radially inwards, as shown in FIG. 10B. The sensor 91 is moved to a position where it can measure the thickness of the calibration wafer Wp. Then, since the thickness can be measured by the sensor 91 above the calibration wafer Wp, the position above an outer periphery of the calibration wafer Wp where the corresponding thickness has been measured is set as an outer peripheral position P1 of the sensor 91. The outer peripheral position P1 is an outer peripheral position of the calibration wafer Wp and is a measurement point (outer peripheral point) in the radial direction of the wafer W. The outer peripheral position P1 thus set is output from the moving mechanism 92 to the controller 140 and registered.

After the outer peripheral position P1 of the sensor 91 is set, the controller 140 sets and registers a mid-position P2 and a center position P3 shown in FIG. 10C. The mid-position P2 is a position of R/2 from the center of the calibration wafer Wp, and is a measurement point (mid-point) of the wafer W in the radial direction. An offset amount of the mid-position P2 from the outer peripheral position P1 is preset, so the mid-position P2 is set after the outer peripheral position P1 is set. The center position P3 is a center position of the calibration wafer Wp, and is a measurement point (center point) of the wafer W in the radial direction. An offset amount of the center position P3 from the outer peripheral position P1 is also previously set, so the center position P3 is set after the outer peripheral position P1 is set.

According to the present exemplary embodiment, the radial positions P1, P2, and P3 of the sensor 91 can be appropriately set, so that the automatic Z-axis setting of the sensor 91 can be appropriately carried out.

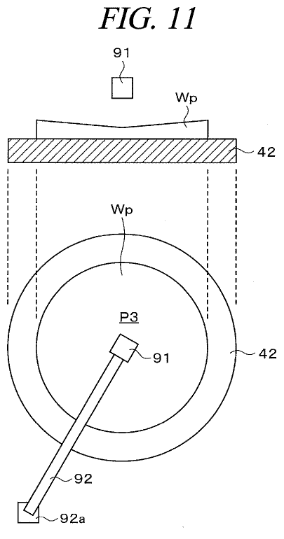

Further, the method of setting the radial positions P1, P2, and P3 of the sensor 91 is not limited to the above. By way of example, a calibration wafer Wp with a recessed center position P3 as shown in FIG. 11 may be used. A thickness T of the calibration wafer Wp at the center position P3 is known in advance and is the smallest within the calibration wafer Wp.

In this case, the sensor 91 on standby at the standby position PO is rotated and moved inwards by the moving mechanism 92. The sensor 91 is moved to a position where it can measure the thickness T. The position of the sensor 91 where the thickness T has been measured is set as the center position P3 of the sensor 91. An offset amount between the center position P3 and the mid-position P2 and an offset amount between the center position P3 and the outer peripheral position P1 are set in advance. Thus, after the center position P3 is set, the mid-position P2 and the outer peripheral position P1 are set.

Further, in the above-described exemplary embodiment, the radial positions of each of the sensors 91, 108, 118, and 128 are set at the three points, but the number of the radial positions is not limited thereto. By way of example, two radial positions may be set, or four or more radial positions may be set.

The operation screen 200 for performing the automatic Z-axis setting of the sensors 91, 108, 118, and 128, which is displayed on the display panel 130 of the grinding apparatus 1 according to the above-described exemplary embodiment, is not limited to the example shown in FIG. 4. For instance, if a contact-type thickness measurement module is provided at the processing position A1 instead of the non-contact-type thickness measurement module 107, the automatic Z-axis setting of the sensor 108 is not performed at the processing position A1, and the automatic Z-axis setting progress table 210 remains blank.

Also, on the operation screen 200 shown in FIG. 4, the delivery position AO and the processing positions A1 to A3 are all displayed. However, the automatic Z-axis setting of the sensor 91 at the delivery position AO, the automatic Z-axis setting of the sensor 108 at the processing position A1, the automatic Z-axis setting of the sensor 118 at the processing position A2, and the automatic Z-axis setting of the sensor 128 at the processing position A3 may be displayed on different screens.

Moreover, although the operation screen 200 shown in FIG. 4 illustrates the example in which the chuck 42A is self-ground, the operation screen 200 may also be able to display a case in which the multiple chucks 42A to 42D are self-ground. In such a case, the alarm indicating that the automatic Z-axis setting of the sensors 91, 108, 118, and 128 has not been performed is displayed in the automatic Z-axis setting progress table 210, for each the chucks 42A to 42D that have been self-ground.

In addition, the operation screen 200 shown in FIG. 4 is provided with the single Z-axis setting button 220, and by pressing this Z-axis setting button 220, the automatic Z-axis setting of the sensors 91, 108, 118, and 128 is started. However, the Z-axis setting button 220 may be provided separately for each of the delivery position AO and the processing positions A1 to A3. In such a case, the timing for the automatic Z-axis setting of the sensors 91, 108, 118, and 128 at the delivery position AO and the processing positions A1 to A3 can be set individually.

In the grinding apparatus 1 according to the above-described exemplary embodiment, the automatic Z-axis setting of the sensors 91, 108, 118, and 128 is performed using the calibration wafer Wp stored in the calibration wafer storage 70. However, the calibration wafer Wp may be transferred from the outside of the grinding apparatus 1. In such a case, the calibration wafer storage 70 is omitted, and a cassette C accommodating a plurality of calibration wafers Wp is placed on the cassette placement table 10 of the carry-in/out station 2.

The grinding apparatus 1 according to the above-described exemplary embodiment has a three-axis configuration equipped with the rough grinder 100, the intermediate grinder 110, and the finishing grinder 120. However, the grinding apparatus 1 may have a one-axis or two-axis configuration. Whether it is one-axis configuration or two-axis configuration, the technology of the present disclosure can be applied to each grinder.

Although the above exemplary embodiment has been described for the case where the automatic Z-axis setting of the sensors 91, 108, 118, and 128 is performed in the grinding apparatus 1, the apparatus to which the position setting method for the thickness measurer of the present disclosure is applied is not limited to the grinding apparatus. By way of example, the technology of the present disclosure is also applicable to an apparatus for measuring the thickness of a substrate before or after etching of the substrate.

It should be noted that the above-described exemplary embodiments are illustrative in all aspects and are not anyway limiting. The above-described exemplary embodiments may be omitted, replaced and modified in various ways without departing from the scope and the spirit of claims. For example, the constitutional elements of the above-described exemplary embodiments may be combined in various ways. From any of these various combinations, functions and effects for the respective constituent elements are naturally obtained, and other functions and other effects obvious to those skilled in the art are also obtained from the description of the present specification.

In addition, the effects described in the present specification are only explanatory or illustrative and are not limiting. That is, the technique according to the present disclosure may exhibit, together with or instead of the above-stated effects, other effects obvious to those skilled in the art from the description of the present specification.

### EXPLANATION OF CODES

1: Grinding apparatus
42: Chuck
91: Sensor
100: Rough grinder
101: Rough grinding whetstone
108: Sensor
110: Intermediate grinder
111: Intermediate grinding whetstone
118: Sensor
120: Finishing grinder
121: Finishing grinding whetstone
128: Sensor
La: Measurement light
Lb: Reflection light
W: Wafer
Wp: Calibration wafer

1. A position setting method of a thickness measurer configured to measure a thickness of a substrate by using measurement light in a grinding apparatus configured to grind the substrate, the position setting method of the thickness measurer comprising:
holding a calibration substrate with a substrate holder;
irradiating the calibration substrate with the measurement light from the thickness measurer, while moving the thickness measurer closer to or away from the calibration substrate;
acquiring intensity of reflection light of the measurement light reflected on the calibration substrate; and
setting a position of the thickness measurer at which the acquired intensity of the reflection light becomes an optimal value as a thickness measurement position of the substrate.

2. The position setting method of the thickness measurer of claim 1,
wherein the optimal value is a maximum value of the intensity of the reflection light.

3. The position setting method of the thickness measurer of claim 1, further comprising:
moving, when a thickness of the calibration substrate and the thickness of the substrate before grinding are different, the thickness measurer from the thickness measurement position to correspond to the thickness of the substrate before grinding.

4. The position setting method of the substrate thickness measurer of claim 1,
wherein before the calibration substrate is held by the substrate holder, self-grinding of the substrate holder is performed.

5. The position setting method of the thickness measurer of claim 4, further comprising:
outputting, after performing the self-grinding of the substrate holder, an alarm indicating that the setting of the position of the thickness measurer is not performed; and
setting the position of the thickness measurer as the thickness measurement position of the substrate, and canceling the alarm.

6. The position setting method of the thickness measurer of claim 1,
wherein when a position setting button for the thickness measurer on an operation screen is pressed before the calibration substrate is held by the substrate holder, the calibration substrate is transferred to the substrate holder.

7. The position setting method of the thickness measurer of claim 1,
wherein the setting of the position of the thickness measurer is performed at a radial position which is a same as a radial measurement position of the substrate when the thickness of the substrate is measured.

8. The position setting method of the thickness measurer of claim 7,
wherein the radial position includes multiple radial positions,
the radial measurement position includes multiple radial measurement positions,
measurement of the thickness of the substrate is performed at the multiple radial measurement positions of the substrate, and
the setting of the position of the thickness measurer is performed for each of the multiple radial positions which are a same as the multiple radial measurement positions.

9. The position setting method of the thickness measurer of claim 8,
wherein the multiple radial measurement positions are positions where the thickness of the substrate is measured by using the thickness measurer after the substrate is ground.

10. A grinding apparatus configured to grind a substrate, comprising:
a substrate holder;
a grinder, having a grinding whetstone configured to grind the substrate holder or the substrate held by the substrate holder, configured to move the grinding whetstone relative to the substrate or the substrate holder;
a thickness measurer configured to measure a thickness of the substrate by using measurement light; and
a controller,
wherein the controller controls:
holding a calibration substrate with the substrate holder;
irradiating the calibration substrate with the measurement light from the thickness measurer, while moving the thickness measurer closer to or away from the calibration substrate;
acquiring, from the thickness measurer, intensity of reflection light of the measurement light reflected on the calibration substrate; and
setting a position of the thickness measurer at which the acquired intensity of the reflection light becomes an optimal value as a thickness measurement position of the substrate.

11. The grinding apparatus of claim 10,
wherein the optimal value is a maximum value of the intensity of the reflection light.

12. The grinding apparatus of claim 10,
wherein when a thickness of the calibration substrate and the thickness of the substrate before grinding are different, the controller further controls moving the thickness measurer from the thickness measurement position to correspond to the thickness of the substrate before grinding.

13. The grinding apparatus of claim 10,
wherein the controller further controls:
outputting, after performing self-grinding of the substrate holder, an alarm indicating that the setting of the position of the thickness measurer is not performed; and
setting the position of the thickness measurer as the thickness measurement position of the substrate, and canceling the alarm.

14. The grinding apparatus of claim 10, further comprising:
an operation screen on which a position setting button for the thickness measurer is displayed.

15. The grinding apparatus of claim 14, further comprising:
a calibration substrate storage; and
a transfer device configured to transfer the calibration substrate between the calibration substrate storage and the substrate holder,
wherein the controller further controls transferring, when the position setting button for the thickness measurer on the operation screen is pressed, the calibration substrate to the substrate holder by the transfer device.

16. The grinding apparatus of claim 10,
wherein the controller further controls performing the setting of the position of the thickness measurer at a radial position which is a same as a radial measurement position of the substrate when the thickness of the substrate is measured.

17. The grinding apparatus of claim 10,
wherein the controller further controls:
performing measurement of the thickness of the substrate at multiple radial measurement positions of the substrate; and
performing the setting of the position of the thickness measurer for each of multiple radial positions which are a same as the multiple radial measurement positions.

18. The grinding apparatus of claim 17,
wherein the multiple radial measurement positions are positions where the thickness of the substrate is measured by using the thickness measurer after the substrate is ground.
